(19) United States
(12) Patent Application Publication
(10) Pub. No.: US 2024/0275127 A1
(43) Pub. Date: Aug. 15, 2024

(54) SEMICONDUCTOR CHIP AND COMPONENT

(71) Applicant: ams-OSRAM International GmbH, Regensburg (DE)

(72) Inventors: Jörg Erich SORG, Regensburg (DE); Erik HEINEMANN, Regensburg (DE); André SOMERS, Obertraubling (DE); Thomas KIPPES, Neumarkt (DE); Sebastian SCHLEGL, Bad Abbach (DE); Matthias HEIDEMANN, Regenstauf (DE)

(73) Assignee: ams-OSRAM International GmbH, Regensburg (DE)

(21) Appl. No.: 18/568,308

(22) PCT Filed: Jun. 9, 2022
(86) PCT No.: PCT/EP2022/065697

§ 371 Date: Dec. 8, 2023

(30) Foreign Application Priority Data
Jun. 11, 2021 (DE) 102021115231.3
Sep. 6, 2021 (DE) 102021123015.2

(51) Int. Cl. H01S 5/042; H01S 5/02315; H01S 5/22

(52) U.S. Cl. CPC H01S 5/04257; H01S 5/02315; H01S 5/22

(57) ABSTRACT

A semiconductor chip with a structured chip back side is specified, the chip back side being configured for electrical and thermal linking of the semiconductor chip, the semiconductor chip having emitter regions configured for producing electromagnetic radiation and the structured chip back side having connection pads configured for electrical linking of the emitter regions. The connection pads are p-contacts or n-contacts, with, in a plan view, all connection pads (which are configured either as p-contacts or as n-contacts overlapping with at least two of the emitter regions in each case and each of these connection pads being configured for electrical linking of only one of the emitter regions. Moreover, a component is specified, in particular comprising at least one such semiconductor chip.

### CROSS-REFERENCE TO RELATED APPLICATIONS

The present application is a national stage entry from International Application No. PCT/EP2022/065697, filed on Jun. 9, 2022, published as International Publication No. WO 2022/258756 A9 on Dec. 15, 2022, and claims priority to German Patent Application Nos. 10 2021 115 231.3, filed Jun. 11, 2021, and 10 2021 123 015.2, filed on Sep. 6, 2021, the disclosures of all of which are hereby incorporated by reference in their entireties.

### FIELD

A semiconductor chip is specified. Furthermore, a component is specified.

### BACKGROUND

Semiconductor chip or a plurality of semiconductor chips is/are often mounted on an external carrier, for example on a standardized chip-submount, and electrically and thermally conductively connected to it. Uniform thermal and electrical connection of semiconductor chips is desirable in many cases. In many cases, small pitch distances, such as emitter distances, between the semiconductor chips or between the radiation emitting regions of one semiconductor chip are desirable.

One object is to specify a semiconductor chip and a component with improved properties with respect to electrical and thermal interconnection and/or with small pitch distances or emitter distances.

This object is solved by a semiconductor chip and a component according to the independent claims. Further embodiments and further developments of the semiconductor chip and of the component are the subject-matter of the dependent claims.

### SUMMARY

In at least one embodiment of a semiconductor chip, it has a structured chip bottom side that is configured to electrically and thermally connect the semiconductor chip.

In at least one further embodiment of a semiconductor chip, it has a structured chip bottom side that is configured for electrical and thermal connection of the semiconductor chip. The semiconductor chip has emitter regions that are configured to generate electromagnetic radiation. The structured chip bottom side has connection pads which are configured for the electrical connection of the emitter regions. The connection pads are p-contacts or n-contacts, wherein in top view, all connection pads formed either as p-contacts or as n-contacts overlap with at least two of the emitter regions and are each configured for the electrical connection of only one of the emitter regions.

According to at least one embodiment of the semiconductor chip, it has emitter regions that are configured to generate electromagnetic radiation. The structured chip bottom side has connection pads that are configured for electrical connection of the emitter regions. For example, the semiconductor chip is a double-emitter or a multiple-emitter, such as a triple-emitter or a quadruple-emitter. It is possible that the emitter regions are integral parts of a common semiconductor body of the semiconductor chip.

In particular, the emitter regions are defined by so-called ridge regions, or ridges. A semiconductor chip with such ridge regions is also called a ridge laser or a stripe laser. Such a semiconductor chip may have one or more stripe waveguides formed in a semiconductor region of the semiconductor chip. Such stripe waveguide may be configured for one-dimensional wave-guiding along a wave-guiding direction of a laser radiation generated in an active region of the semiconductor chip. If the semiconductor chip has two or more emitter regions, the semiconductor chip may have two or more such stripe waveguides.

For example, the emitter region or stripe waveguide extends along a lateral direction of the semiconductor body of the semiconductor chip. In particular, the stripe waveguide is in the form of a ridge projecting along a vertical direction. If the semiconductor chip has a plurality of emitter regions, the semiconductor chip can have, in top view, a plurality of stripe waveguides arranged next to one another, in particular in the form of protruding ridges arranged next to one another.

A lateral direction is understood to mean a direction that is in particular parallel to a main extension surface of the semiconductor chip, for example to a main extension surface of the semiconductor body of the semiconductor chip. A vertical direction is understood to mean a direction which is directed in particular perpendicularly to the main extension surface of the semiconductor chip or of the semiconductor body. The vertical direction and the lateral direction are orthogonal to each other.

For example, the semiconductor chip is an edge-emitting semiconductor chip. In an edge-emitting semiconductor chip, which is, for example, a ridge-laser or a stripe laser, laser radiations are coupled out at a lateral surface of the semiconductor chip. The generated laser radiations propagate essentially along a lateral direction parallel to the stripe waveguide.

According to at least one embodiment of the semiconductor chip, the structured chip bottom side has a plurality of connection pads via which the emitter regions can be electrically externally connected, for example via a contact structure of a carrier. It is possible that the emitter regions can be electrically contacted individually via the connection pads. For example, the number of connection pads assigned to the same electrical polarity of the semiconductor chip is equal to or greater than the number of emitter regions. Each of the emitter regions may be electrically connected to only one connection pad or to multiple connection pads.

According to at least one embodiment of the semiconductor chip, the chip bottom side is formed in a honeycombed or matrix-like manner. In particular, the connection pads on the chip bottom side are arranged in a honeycombed or matrix-like manner.

In particular, the structured chip bottom side has at least one n-contact or several n-contacts and at least one p-contact or several p-contacts. In particular, the semiconductor chip is free of wire bonds. Avoiding wire bonds improves signal propagation times, high frequency performance and impedance.

For example, the structured chip bottom side has further additional connection pads in addition to the connection pads, wherein the connection pads form p-contacts and the further additional connection pads form n-contacts, or vice versa. For example, the connection pads and the further additional connection pads are located on a common plane, such as on a common rewiring plane.

With such a semiconductor chip, pitch distances can be used that are difficult to realize with conventional interconnection techniques. The use of a rewiring plane, in particular a single rewiring plane, allows small pitch distances or ridge distances.

According to one embodiment of the semiconductor chip, the pitch distances, ridge distances or waveguide distances are less than 50 μm, 30 μm or less than 20 μm, for example from 5 μm to 50 μm.

In particular, the waveguide structure faces a mounting surface of a carrier (submount), especially for reasons of improved heat dissipation. The mounting of a semiconductor chip or of several semiconductor chips for instance on the same mounting plane results in narrow pitch distances or ridge distances or in an improved tolerance with respect to compliance with the desired pitch distances or ridge distances. In particular, the tolerance chain is improved. It is possible that all emission points are located on one plane.

The connection of many p- and n-contacts with a tight arrangement (pitches can be smaller than 50 μm or 30 μm, for example) can be realized. For example, the n-side of the semiconductor chip is connected from below, in particular from the same side or from the common contacting plane as the p-side. The embodiments of a semiconductor chip or component described here differ from the case where the p-contacts and the n-contacts are arranged on two different sides.

A substrate of the semiconductor chip, such as a GaN substrate, can be undoped. In other words, the substrate no longer needs to be doped to make it electrically conductive. This improves the crystal quality. The EPI quality is also improved. This leads to improved performance of the semiconductor chip. The electrical series resistance can be reduced because the current is no longer conducted through the entire substrate. This means that Uf is lowered. This means that the power dissipation of the semiconductor chip is also reduced. Finally, this increases the so-called WPE (Popt/Pel=Wall-plug Efficiency), i.e. the socket efficiency or the overall efficiency.

In particular, several semiconductor chips can be mounted on the same mounting plane. This also improves the tolerance chain (elimination of chip thickness influence). All emission points of the semiconductor chips can be on one plane. In particular, one, for example only one, rewiring plane is needed to provide the contact pads or connection pads of the semiconductor chip or semiconductor chips, for example, for the mounting on a carrier (submount). For example, a bonding wire connection is not required to connect the semiconductor chip on a carrier. However, the carrier may have bond wire connections.

The embodiments of a semiconductor chip or component described herein result in improved image quality, such as color homogeneity and resolution. With multi-ridge semiconductor chip, it is brighter, and there are less negative effects regarding flickering. i.e. regarding glimmering. Due to narrow waveguide spacing, the assembly requires only a small mounting space and low optical complexity. It is possible to realize subpixel modulation, e.g. in small time intervals. For each pixel, the red, green, or blue laser (r, g, or b laser) can be turned on for a few nanoseconds. For example, 10 nanoseconds are divided into several short pulses. The semiconductor chip or the laser is over-currented, for example with 50% duty cycle. The spectrum can be broadened in this way. This leads to improved image quality.

Brightness dimming can be achieved via pulse width modulation. By suppressing optical artifacts in the optical system (e.g. in glasses, such as data glasses, AR glasses or VR glasses), a wider spectrum can be achieved. In addition, rgb-emission points are narrower. A larger overlapping region from the r, g and b pixel leads to a better image illustration or better field of view, since rgb pixel can be “written” with multiple colors at the same time. Especially from the point of view of a glasses-architecture, narrow emitter spacing is desirable because multiple pixels can be written in parallel. However, this is difficult to realize at the edge of the glasses.

Multiridges can be combined with a smaller lens, resulting in an improvement of squint angle and correction. It also results in a smaller form factor for the engine. High current performance may be less important when more ridges are present, or when wavelength tuning is possible. The operating current required to drive the chip just below the threshold becomes lower. For achieving fast switching times, the semiconductor chip, especially the laser, is operated just below the threshold. Higher power is often associated with a higher threshold. By connecting multiple emitting regions in parallel, such as multiple semiconductor chips or lasers, power consumption is reduced for the same optical power, while dynamic brightness control is improved.

By distributing the currents over several radiation-emitting regions, such as several ridges, the current consumption per region/ridge is reduced. This allows shorter switching times to be realized.

In at least one embodiment of a carrier, the carrier has a structured contact surface configured to receive and electrically contact one semiconductor chip or a plurality of semiconductor chips.

In at least one embodiment of a component, the latter has at least one semiconductor chip, in particular a semiconductor chip described here, and a carrier, wherein the at least one semiconductor chip is arranged on the carrier and is electrically conductively connected to the carrier via a structured contact structure of the carrier.

In at least one embodiment of a component, it comprises at least one semiconductor chip and a carrier. The semiconductor chip is arranged on the carrier. In particular, the semiconductor chip is electrically conductively connected to the carrier via a structured contact structure.

For example, the structured contact structure is of a honeycomb or a contact pad structure. Deviating from this, the structured contact structure can be matrix-like. For example, the contact structure is a chip bottom side, a contact surface of the carrier, or a combination of the chip bottom side and the contact surface of the carrier.

In this disclosure, the component is often described by the semiconductor chip with the carrier for the sake of clarity. However, the features described in connection with the component can also be used separately for the semiconductor chip or separately for the carrier, or at least used analogously, and vice versa.

It is possible that a plurality of semiconductor chips are arranged on the carrier (submount) and are electrically and/or thermally conductively connected to it. It is also possible that the semiconductor chip has a single semiconductor body, a structured semiconductor body or several semiconductor bodies, in particular for generating electromagnetic radiation. The semiconductor body may be in the form of one ridge or more ridges. In particular, the semiconductor body has a plurality of ridges, i.e. a plurality of radiation emitting regions. The ridges or the radiation-emitting regions can be electrically contacted in particular separately, i.e. individually.

For example, the semiconductor chip is a radiation-emitting semiconductor chip, such as a laser, a thin-film LED, a VCSEL, an HCSEL, an edge-emitting laser, a ridge laser, a flip chip, or a pixelated LED. Also, the semiconductor chip can be in the form of a laser array, such as a VCSEL array.

A component with at least one such semiconductor chip can be used in a display, in a projector (for example as a pico-laser, power laser, single- or multi-mode laser), in data glasses, AV or AR glasses (Augmented Reality glasses, Virtual Reality glasses), or in areas of so-called “Augmented and Virtual Reality” or in the automotive industry. The component or semiconductor chip can be in the form of a laser bar.

According to at least one embodiment of the component, a chip top side, for example an n-side top side of the component or of the semiconductor chip, has a structuring, for example a structured electrical contact surface. The chip top side may be arbitrarily structured. The component may have a plurality of semiconductor chips. It is also possible for the component to have a single semiconductor chip with a plurality of radiation emitting regions. The structured chip top side, in particular the structured electrical contact surface, can be formed for electrical contacting, in particular for individual electrical contacting of the semiconductor chips or of the radiation-emitting regions of the semiconductor chip.

According to at least one embodiment of the component, a chip bottom side, for example a p-side bottom side of the semiconductor chip or a p-side bottom side of a plurality of semiconductor chips, can be adapted or fitted to the chip top side via the structured contact structure, for example via the honeycomb/contact pad structure.

It is also possible that the chip top side is formed as p-side and the chip bottom side is formed as n-side. Furthermore, it is possible that the p-contact/s and the n-contact/s of the semiconductor chip or component are on a common plane. The p-contact/s and the n-contact/s of the semiconductor chip or of the semiconductor chips may be on a common plane. For example, the common plane is an interface between the semiconductor chip or semiconductor chips and the carrier. The common plane may be a chip-submount interface.

According to at least one embodiment of the component, the carrier has a structured contact surface. The structured contact surface of the carrier may be adapted to the electrical contact points of the semiconductor chip or of the semiconductor chips. The contact points of the semiconductor chip or of the semiconductor chips may be formed by connection pads on the bottom side of the semiconductor chip or on the bottom sides of the semiconductor chips. For example, the structured contact surface of the carrier has a plurality of contact pads arranged side by side. In particular, the structured contact surface of the carrier has a honeycomb structure.

According to at least one embodiment of the component, the semiconductor chip comprises a semiconductor body. The semiconductor body may be electrically conductively connected to the contact pads on the carrier via an electrical distribution layer and/or via connection pads. The contact pads on the carrier may be components of the structured contact surface of the carrier.

According to at least one embodiment of the component or of the semiconductor chip, the electrical distribution layer is arranged between the semiconductor body and the carrier. In particular, a single insulating layer or a single insulating plane is arranged between the electrical distribution layer and the carrier. For example, a single insulating layer or a single insulating plane is located in the vertical direction between the electrical distribution layer and the connection pads on the bottom side of the chip.

Through-contacts can be arranged in the insulating layer or in the insulation plane. In particular, the component or the semiconductor chip has a single rewiring or contacting plane.

The insulating layer can have at least one opening or several openings. An electrically conductive through-contact can be formed in the respective opening. Via the through-contact or via a plurality of through-contacts, the electrical distribution layer can be electrically conductively connected to one or more connection pads. For example, the connection pads are located on the chip bottom side. In particular, the connection pads are electrical contact points of the semiconductor chip or semiconductor chips. The connection pads can, for example, be electrically and in particular also thermally connected to the contact pads of the structured contact area of the carrier via one or more connecting layers.

In particular, carrier groups or submount groups can be formed that cover multiple chip designs. This means fewer variants and fewer logistics for different chip designs. The chip-submount interface can be standardized in terms of process, in particular with regard to the connection of the semiconductor chip or of the semiconductor chips on the carrier. The interface can always be identical for different chip designs. Also, the same material or identical materials of the contact area of the carrier can be used for different chip designs. The contact area of the carrier can have the same structure for different chip designs. Also, the same interconnect technology can be used for different chip designs or for multiple chip types.

If the contact surface of the carrier has a plurality of contact pads arranged next to each other or a plurality of honeycombs, the interconnection of several, in particular the maximum possible contact pads or honeycombs, results in the best possible thermal dissipation.

According to at least one embodiment, the semiconductor body or ridge is electrically connected via several sub-regions of the contact surface of the carrier, in particular via several honeycombs or contact pads. In this way, uniform current injections can be achieved.

The distribution layer, in particular in the form of a metallization, can be adapted with regard to its layer thickness. In this way, the current-carrying capacity and the heat spread in the immediate vicinity of the ridge or the radiation-emitting region of the semiconductor body can be adjusted and improved upon request.

Overall, the thermal and electrical connection of semiconductor chips, in particular of optoelectronic chips, can be improved with multiple contacts (connections, ridges) on the mounting side. Optimized thermal connection and current injections can be achieved in particular by possible connection of the semiconductor chip at multiple positions. The contact pads of the contact area of the carrier can also be standardized, wherein a standardized assembly and connection technology can be achieved.

### BRIEF DESCRIPTION OF THE DRAWINGS

Further embodiments and further developments of the semiconductor chip or of the component will become apparent from the exemplary embodiments explained below in connection with FIGS. 1 to 10D.

FIG. 1 shows a component in sectional view,

FIGS. 2A, 2B, 2C, 2D and 2E show schematic illustrations of several exemplary embodiments of a component with different contacting options of the semiconductor chip or of the semiconductor chips,

FIGS. 3A, 3B, 3C and 3D show schematic illustrations of several exemplary embodiments of a component with different embodiments of the contact surface of the carrier,

FIG. 4 shows schematic illustration of a component with a honeycomb structure,

FIGS. 5 and 6 show schematic illustrations of further embodiments of a component,

FIGS. 7A and 7B show schematic illustrations of further contacting options,

FIGS. 8A and 8B show schematic illustrations of a semiconductor chip on a carrier,

FIGS. 9A, 9B, 9C and 9D show schematic illustrations of various arrangements of the connection pads or the contact pads, and

FIGS. 10A, 10B, 10C, and 10D show schematic illustrations of further exemplary embodiments of a semiconductor chip or component.

### DETAILED DESCRIPTION

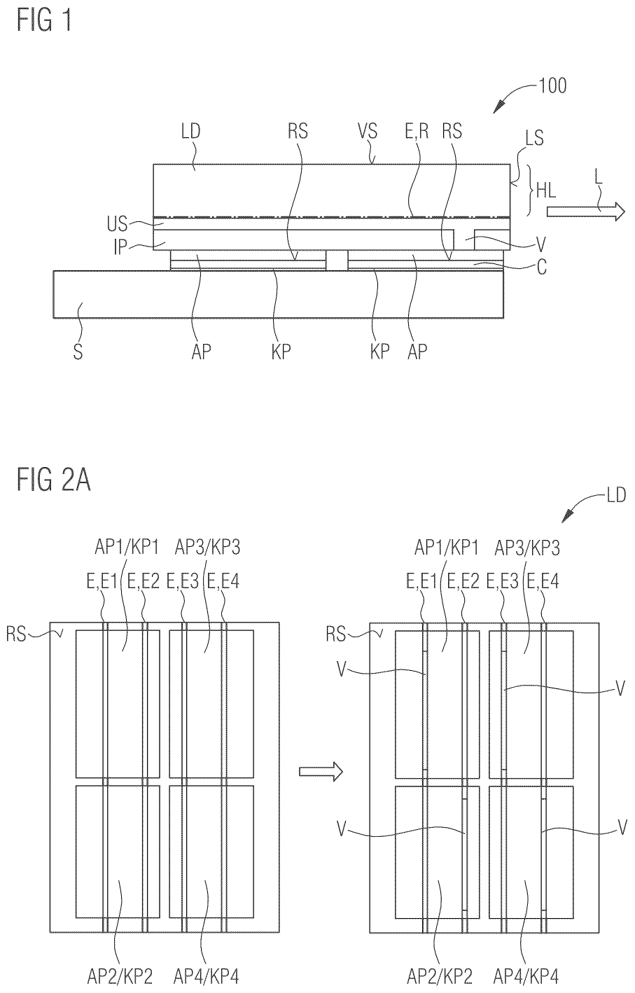

Identical, equivalent or equivalently acting elements are indicated with the same reference numerals in the figures. The figures are schematic illustrations and thus not necessarily true to scale. Comparatively small elements and particularly layer thicknesses can rather be illustrated exaggeratedly large for the purpose of better clarification. FIG. 1 shows a component 100 having at least one semiconductor chip LD on a carrier S. The semiconductor chip LD has a semiconductor body HL which is configured in particular for generating electromagnetic radiation L. The semiconductor body HL has a first semiconductor layer, a second semiconductor layer and an active zone, for example a pn-junction zone, arranged between the first semiconductor layer and the second semiconductor layer. For example, the semiconductor body HL has a first semiconductor layer, a second semiconductor layer and an active region, such as a pn junction region, arranged between the first semiconductor layer and the second semiconductor layer, wherein the active region is configured to generate electromagnetic radiation, in particular coherent electromagnetic radiation, during operation of the semiconductor chip HL.

The semiconductor chip LD can be a laser. For example, the semiconductor chip LD is a ridge laser. The semiconductor chip LD has an active region R. In particular, the active region R is a sub-region of the active region of the semiconductor body HL. For example, the active region R is a ridge region. The semiconductor chip LD or the semiconductor body HL of the semiconductor chip LD may have a plurality of sub-regions, such as sub-regions E1, E2, E3, E4, each forming, for example, an emitter or an emitter region. The sub-regions may be spatially spaced apart from each other or may form a continuous structure. It is also possible that a plurality of semiconductor chips LD, each forming an emitter or an emitter region E1, E2, E3, or E4, are arranged on the carrier S. The emitters or the emitter regions may each have an active region R, such as a ridge region.

The component 100 has an insulating layer IP or an insulating plane IP disposed in the vertical direction between the semiconductor body HL of the semiconductor chip LD and the carrier S. The insulating layer IP may or may not be an integral part of the semiconductor chip LD. The insulating layer IP may comprise Al nitride, Si nitride, Al oxide and/or Be oxide, or may be formed of at least one of these materials. Such materials exhibit high thermal conductivity.

The insulating layer IP has at least one opening or several openings. A through-contact V is arranged in the respective opening. In particular, the through-contact V extends throughout the insulating layer IP.

The component 100 or the semiconductor chip LD has an electrical distribution layer US, which is arranged in particular between the semiconductor body HL and the insulating layer IP. In particular, the electrical distribution layer US is configured for electrically contacting a semiconductor layer, in particular the p-side or n-side semiconductor layer of the semiconductor body HL. For example, the insulating layer IP forms a single insulating plane of the semiconductor chip LD between the electrical distribution layer US and the chip bottom side RS.

It is possible that the component 100 or the semiconductor chip LD has a plurality of distribution layers US arranged side by side. For example, the distribution layers US are each uniquely associated with one of the emitter regions E1, E2, E3 and E4, and vice versa.

The component 100 or the semiconductor chip LD has a plurality of connection pads AP. The insulating layer IP is arranged in the vertical direction between the electrical distribution layer US and the connection pads AP. In particular, the electrical distribution layer US is electrically conductively connected to one connection pad AP or to a plurality of connection pads AP via one through-contact V or via a plurality of through-contacts V. The surface with the connection pads AP can be referred to as the chip bottom side or the structured chip bottom side RS.

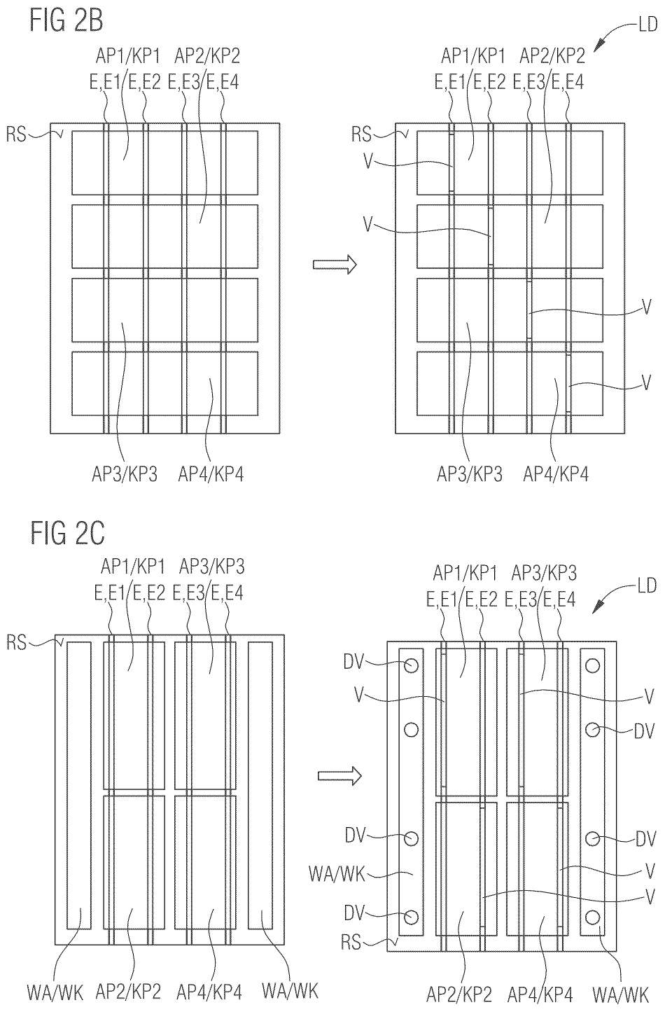

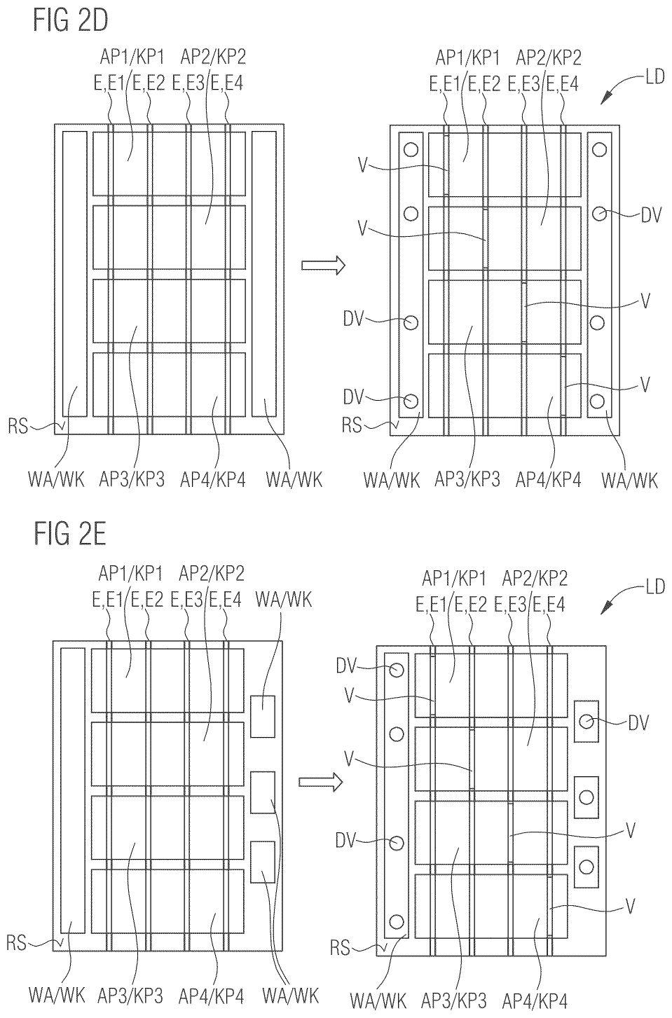

The semiconductor chip LD has a structured chip bottom side RS, which is configured to electrically and thermally connect the semiconductor chip LD. The semiconductor chip LD has emitter regions E, for example, a plurality of emitter regions E1, E2, E3, and E4 (see FIGS. 2A to 2E), which are configured to generate electromagnetic radiation L. The structured chip bottom side RS has a plurality of connection pads AP configured to electrically connect the emitter regions E.

FIG. 1 shows that the semiconductor chip LD has a chip top side VS and a lateral surface LS, wherein the lateral surface LS connects the chip top side VS with the chip bottom side RS. The chip top side VS is in particular a semiconductor top side. The semiconductor chip LD is implemented in particular as an edge-emitting semiconductor chip LD, wherein electromagnetic radiation L is coupled out from the semiconductor chip LD at the lateral surface LS during operation of the semiconductor chip LD.

The semiconductor chip LD has a semiconductor body HL with the emitter regions E, an electrical distribution layer US and an insulating layer IP, wherein the insulating layer IP is arranged in the vertical direction between the semiconductor body HL and the connection pads AP. The insulating layer IP has at least one opening or a plurality of openings, wherein an electrically conductive through-contact V or a plurality of through-contacts V are formed in the opening or openings of the insulating layer IP. The plurality of through-contacts V are schematically shown, for example, in FIGS. 2A to 4. In particular, the through-contact is configured to electrically conductively connect one of the connection pads AP to the electrical distribution layer US. It is possible that one of the connection pads AP or a plurality of the connection pads AP is/are electrically conductively connected to the electrical distribution layer US via the through-contact V or via the through-contacts V.

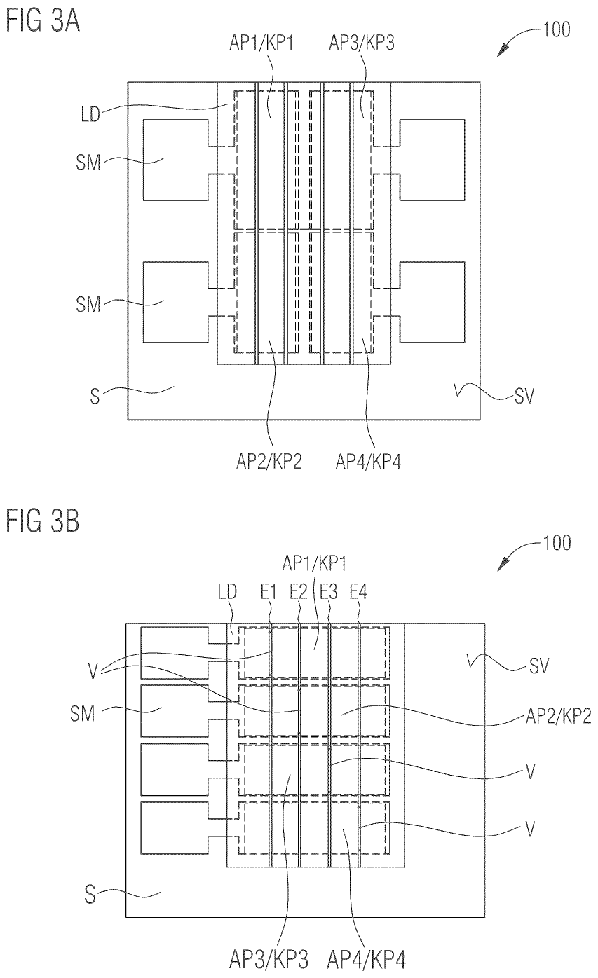

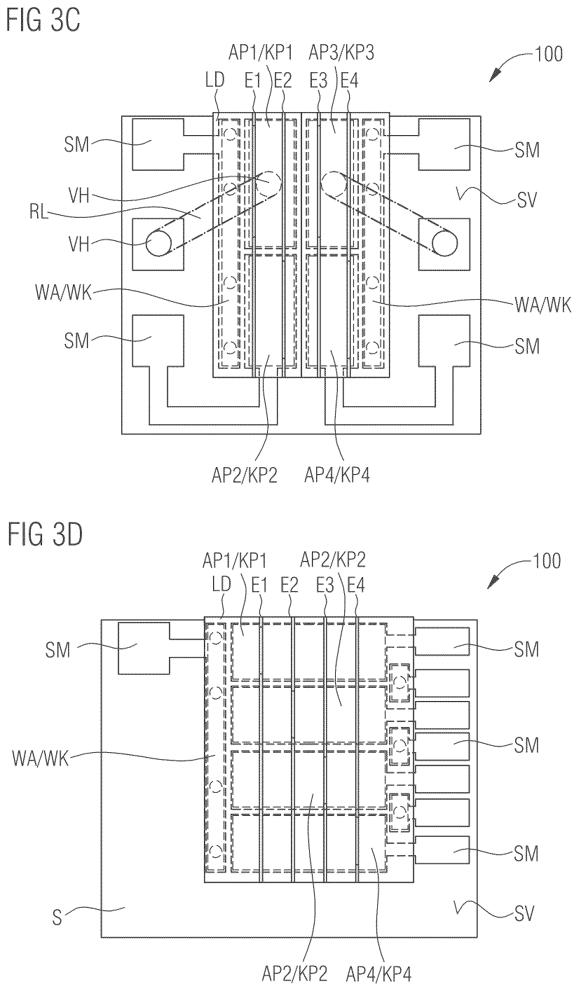

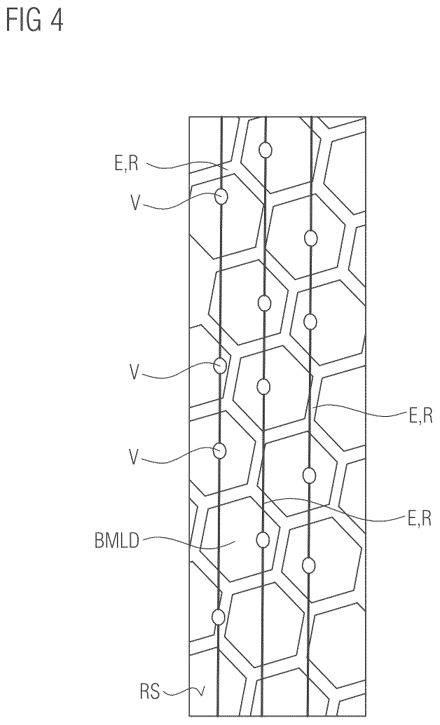

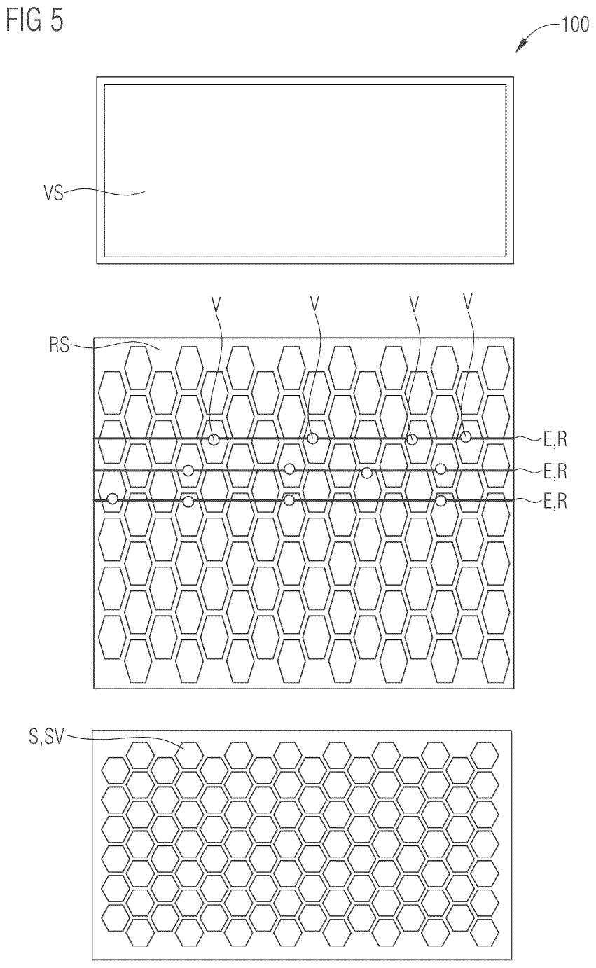

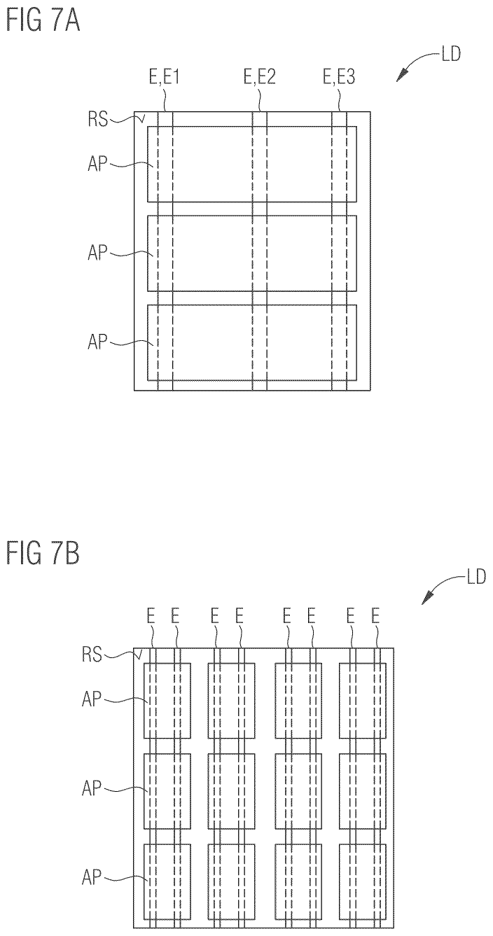

FIGS. 2A to 3D show that the emitter regions E1 to E4 can each be electrically connected via one connection pad AP and one through-contact V. FIGS. 4 and 7B show that it is also possible for an emitter region E1, E2, E3 or E4 to be electrically contactable via a plurality of connection pads AP and a plurality of through-contacts V. A plurality of through-contacts V may be arranged in the insulating layer IP, wherein the electrical distribution layer US is electrically conductively connected to a plurality of connection pads AP via the plurality of through-contacts V. Furthermore, it is possible for each of the emitter regions E1 to E4 to be uniquely assigned to one of the distribution layers US, and vice versa.

The carrier S has a plurality of contact pads KP. The contact pads KP form a contact structure of the carrier S. For example, the component 100 has an electrically conductive connecting layer C or a plurality of electrically conductive connecting layers C. Via the electrically conductive connecting layer/s C, the contact pads KP may be electrically connected to the connection pads AP. In particular, an arrangement of the contact pads KP of the carrier S is adapted to an arrangement of the connection pads AP of the semiconductor chip LD.

FIGS. 2A to 2E show in particular the structured chip bottom side RS according to different implementations. In these figures, possible positions of the contact pads KP1, KP2, KP3 and KP4 associated with the connection pads AP1, AP2, AP3 and AP4 on the carrier S are shown schematically. In FIGS. 2C, 2D and 2E, further connection pads WA and possible positions of the further contact pads WK associated with the further connection pads WA on the carrier S are also shown schematically.

On the left side of the respective FIGS. 2A to 2E, positions of the connection pads AP1, AP2, AP3 and AP4 are schematically shown in relation to the positions of the emitter regions E1, E2, E3 and E4. On the right side of the respective FIGS. 2A to 2E, the electrical contacts of the emitter regions E1, E2, E3 and E4 via the through-contacts V and, for example, also via the further through-contacts DV are shown schematically. The further through-contacts DV connect the semiconductor body HL with the further connection pads WA on the chip bottom side RS.

In particular in top view, at least one of the connection pads AP overlaps with at least two of the emitter regions E1 to E4, wherein the at least one connection pad AP is configured for the electrical connection of only one of the at least two emitter regions. Furthermore, it is possible that in top view, the connection pads AP1-AP4, in particular all connection pads AP, each overlap with at least two of the emitter regions E1-E4 or with exactly two emitter regions. However, the connection pads AP are still each configured for the electrical connection of only one of the emitter regions E1-E4.

FIG. 2A shows an embodiment of a component 100 or a semiconductor chip LD, wherein the connection pads AP1-4 and/or the contact pads KP1-4 each have an overlap with several emitters or emitter regions E1-E4, in particular with two emitters or emitter regions E1-E4 in each case. The connection pads AP1-4 and/or the contact pads KP1-4 can each be configured in particular for electrically contacting a single-emitter or one single emitter region. On the left side, the through-contacts V are not shown. On the right side, it is schematically shown that the connection pads AP1-4 are each electrically conductively connected to one of the emitters or emitter regions E1-E4 via at least one through-contact V. In particular, the connection pads AP1-4 are formed as p-contacts.

The exemplary embodiment shown in FIG. 2B is substantially the same as the exemplary embodiment of a component 100 or a semiconductor chip LD shown in FIG. 2A. In contrast, the connection pads AP1-4 and/or the contact pads KP1-4 each have an overlap with all of the emitters or emitter regions E1-E4 arranged on the carrier S. In particular, the contact pads KP1-4 can be led out laterally on the carrier S.

The exemplary embodiment shown in FIG. 2C essentially corresponds to the exemplary embodiment of a component 100 or a semiconductor chip LD shown in FIG. 2A. In contrast, further connection pads WA or further contact pads WK are located in particular on the same plane as the contact pads KP or as the connection pads AP. In particular, the further connection pads WA and the connection pads AP are assigned to different electrical polarities of the semiconductor chip LD. For example, the connection pads AP form p-contacts and the further connection pads WA form n-contacts of the semiconductor chip LD, or vice versa.

In particular, the further contact pads WK and the contact pads KP are assigned to different electrical polarities of the component 100 or the semiconductor chip LD. For example, the further contact pads WK form n-contacts and the contact pads KP form p-contacts of the component 100, or vice versa. Thus, in particular, no wire-bonds are required on the chip top side, especially on the n-side. For example, the semiconductor body has internal through-contacts DV which extend throughout the active region and are electrically conductively connected to the further connection pads WA or to the further contact pads WK.

The exemplary embodiment shown in FIG. 2D is essentially the same as the exemplary embodiment of a component 100 or semiconductor chip LD shown in FIG. 2B, but very analogously to FIG. 2C with further connection pads WA or further contact pads WK.

The exemplary embodiment shown in FIG. 2E essentially corresponds to the exemplary embodiment of a component 100 or a semiconductor chip LD shown in FIG. 2D. In contrast, the component 100 or semiconductor chip LD has additional further connection pads WA and additional further contact pads WK. In FIG. 2D, two additional further connection pads WA or two additional further contact pads WK are shown. In FIG. 2E, four additional further connection pads WA or four additional further contact pads WK are shown.

According to FIGS. 2A to 2E, the semiconductor chip LD has a plurality of connection pads AP1-AP4 and a plurality of through-contacts V, wherein the connection pads AP1-AP4 each are configured to make electrical contact with one single emitter region E1, E2, E3 or E4. In top view, the connection pads AP1-AP4 each overlap with several emitter regions, in particular exactly with two or four emitter regions. In addition to the connection pads AP1-AP4, the semiconductor chip LD has further connection pads WA, wherein the connection pads AP1-AP4 and the further connection pads WA form p-contacts and n-contacts of the semiconductor chip LD, or vice versa. In particular, the p-contacts and n-contacts, i.e. the connection pads AP1-AP4 and the further connection pads WA of the semiconductor chip LD, are located on the common contacting plane.

FIG. 3A shows a component 100 having another exemplary carrier design for the semiconductor chip LD shown in FIG. 2A. The carrier S has a contact structure with a plurality of contact pads KP1 to KP4 arranged side by side. The carrier S has lateral metallizations SM, each of which is electrically conductively connected to one of the contact pads AP1 to AP4. The lateral metallizations SM can be indicated as submount connection pads. Via such submount connection pads, the submount can be electrically conductively connected to surrounding electrical structures. In particular, the contact pads AP1 to AP4 are arranged between the lateral metallizations SM.

FIG. 3B shows a component 100 with an exemplary carrier design for the semiconductor chip LD shown in FIG. 2B. According to FIG. 3B, all metallizations SM are arranged on the same side of the contact pads AP1 to AP4.

FIG. 3C shows a component 100 having another exemplary carrier design for the semiconductor chip LD shown in FIG. 2C. The carrier S may have further through-contacts VH. The further through-contacts VH may extend throughout a main body of the carrier S. The further through-contacts VH are in particular through-vias in the submount S or in the carrier S. Via the further through-contacts VH, the component 100 can be externally electrically contactable via a rear side of the carrier S, in particular exclusively via the rear side of the carrier S. Deviating from this, a redistribution layer RL in the carrier S is shown schematically in FIG. 3C. Through the redistribution layer RL, an outer metallization SM can be electrically conductively connected to an inner metallization, in particular in the form of a contact pad KP1 or KP3. The redistribution layer RL can be completely embedded in the carrier S.

FIG. 3D shows a component 100 having an exemplary carrier design for the semiconductor chip LD shown in FIG. 2E.

FIG. 4 shows a component 100 or a semiconductor chip LD with a honeycomb structure. The honeycomb structure can be a bottom side metallization BMLD of the semiconductor chip LD. The active region R or the emitter region E, in particular the ridge R, may be electrically connected via several honeycombs, in particular via the through-contacts V. Thus, a uniform current injection can be achieved. Furthermore, a large-area metallic bonding surface of the semiconductor chip LD is achieved via the honeycomb structure. The tilted honeycomb layout can serve as a standardized chip submount interface that can be used for different semiconductor chips LD or for different ridge configurations.

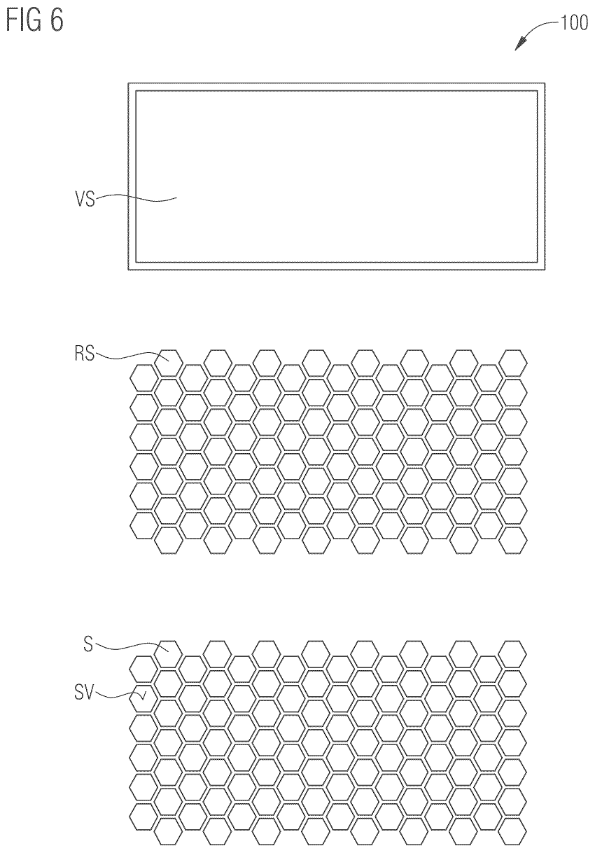

FIGS. 5 and 6 each show a component 100 having a chip top side VS, a chip bottom side RS and a carrier top side SV. The carrier top side SV is adapted to the chip bottom side RS. In particular, the carrier top side SV is formed in a honeycomb-like manner.

The chip top side VS, in particular the n-side, can be structured as desired. The chip bottom side RS, in particular the p-side, can be adapted to the chip top side VS via the honeycomb/contact pad structure. The ridge R or the emitter region E can be electrically connected via several honeycombs/contact pads, thus a uniform current injection can be achieved. In particular, only one rewiring/contacting plane is required. The contact pad design—with only one insulating level—is largely independent of the position and location of the ridges R or the emitter regions E.

An increase in metallization thickness on the ridge R or on the emitter region E, in particular to improve current carrying capacity and/or heat spreading, can be achieved. The rewiring is carried out with only one insulating plane. The insulating plane can have electrical through-contacts V respectively at positions where there is a vertical overlap between the connection metallization, i.e. the connection pad, and the ridge R, i.e. the emitter region E. The insulating plane may have high thermal conductivity and high dielectric strength. The insulating layer, i.e. the insulating layer IP, may be formed of Al-nitride, Si-nitride, Al-oxide, Be-oxide, or similar materials. The connection pads AP or the contact pads KP can be formed with the largest possible surface area. They can cover the largest possible portion of the chip connection plane. In addition, they can cover several emitter regions E, in particular several ridges R, and can improve heat dissipation.

FIGS. 7A and 7B show some further contacting possibilities, namely very analogously to the exemplary embodiments shown in FIGS. 3B and 3C, respectively. In contrast, the connection pads AP according to FIG. 7A may each overlap with three emitter regions E1-E3. According to FIG. 7B, the semiconductor chip LD may have more than four emitter regions E. The connection pads AP can be arranged matrix-like on the chip bottom side RS.

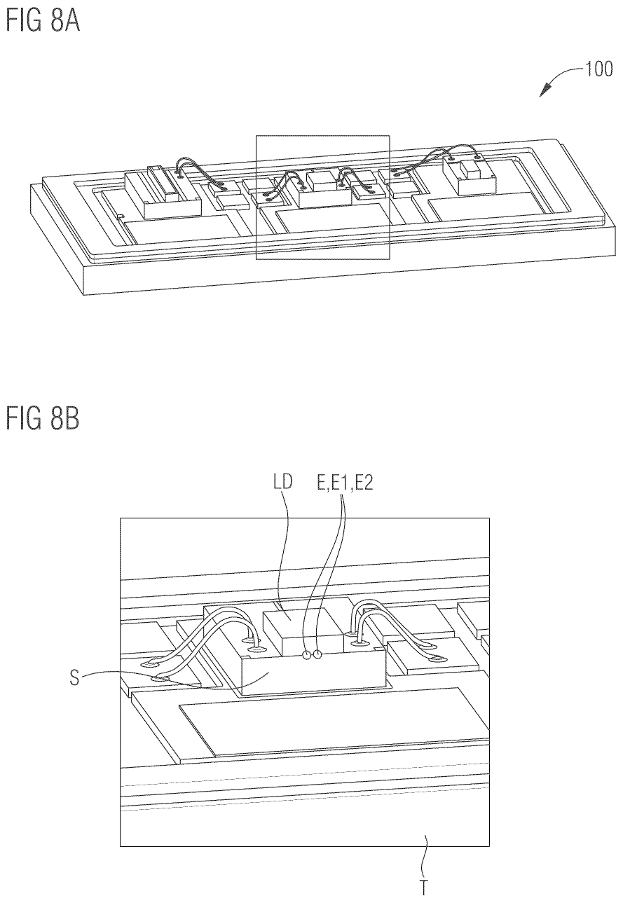

FIG. 8A shows a semiconductor chip LD, which is arranged on a carrier S. The carrier S is arranged on a further submount T, for example on a so-called baseplate T. The submount T is the baseplate of the semiconductor chip.

FIG. 8B shows an enlarged section of FIG. 8A. The semiconductor chip LD can have a plurality of radiation emitting regions, in particular a plurality of emitters or emitter regions E. FIG. 8B schematically shows a semiconductor chip LD with two emitter regions E1 and E2. The distance between the adjacent emitters or emitter regions E1 and E2 can be from 5 μm to 50 μm. The number of emitters or emitter regions may be greater than 2, 3, 4 or greater than 6. The semiconductor chip LD is in particular a so-called multi-emitter. In particular, no bonding wire connections are required for the connection of the semiconductor chip LD. FIG. 8B shows schematically that the bonding wire connections can, however, be used for the electrical connection of the carrier S with contact areas of a baseplate T.

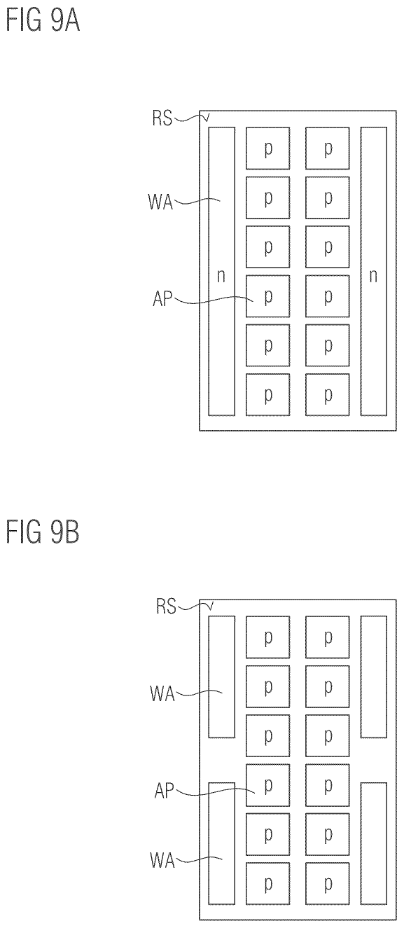

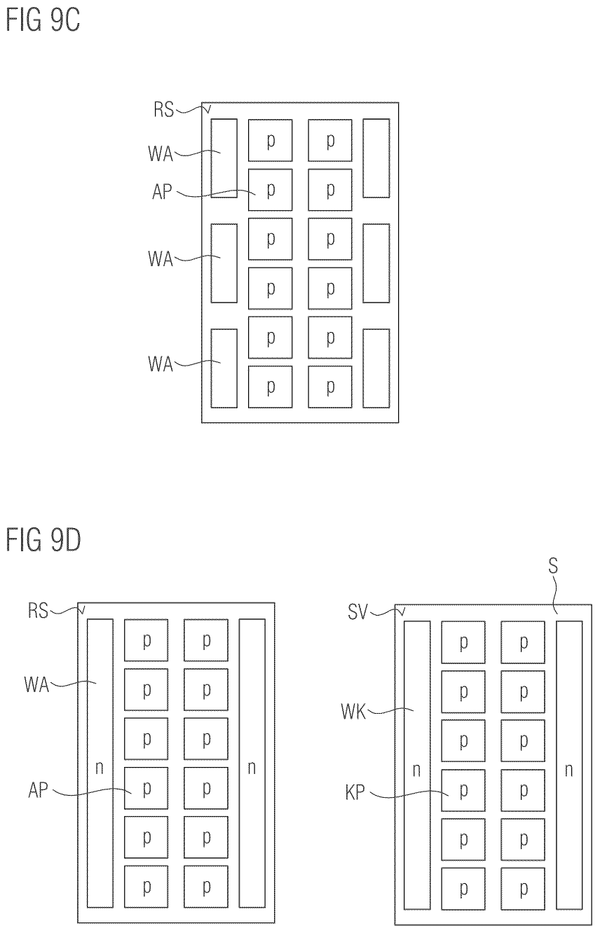

FIGS. 9A, 9B, 9C and 9D show different distributions of the p- and n-connection pads AP or WA, here exemplarily for 12 channels. In particular, the connection pads AP are arranged in a matrix-like manner. FIGS. 9A, 9B and 9C schematically show two, four and six additional connection pads WA, respectively. The connection pads AP and the further additional connection pads WA are assigned to different electrical polarities of the semiconductor chip LD or the component 100. The respective scheme regarding the distribution of the p- and n-connection pads can be scalable and variable regarding the number of channels/ridges, pad size, pad spacing, the regarding the pad segmentation.

FIGS. 9A, 9B and 9C show in particular a structured chip bottom side RS with the connection pads AP and the further connection pads WA. FIG. 9D shows in particular a chip bottom side RS and a modulator side. The modulator side can be defined by a surface of the carrier S.

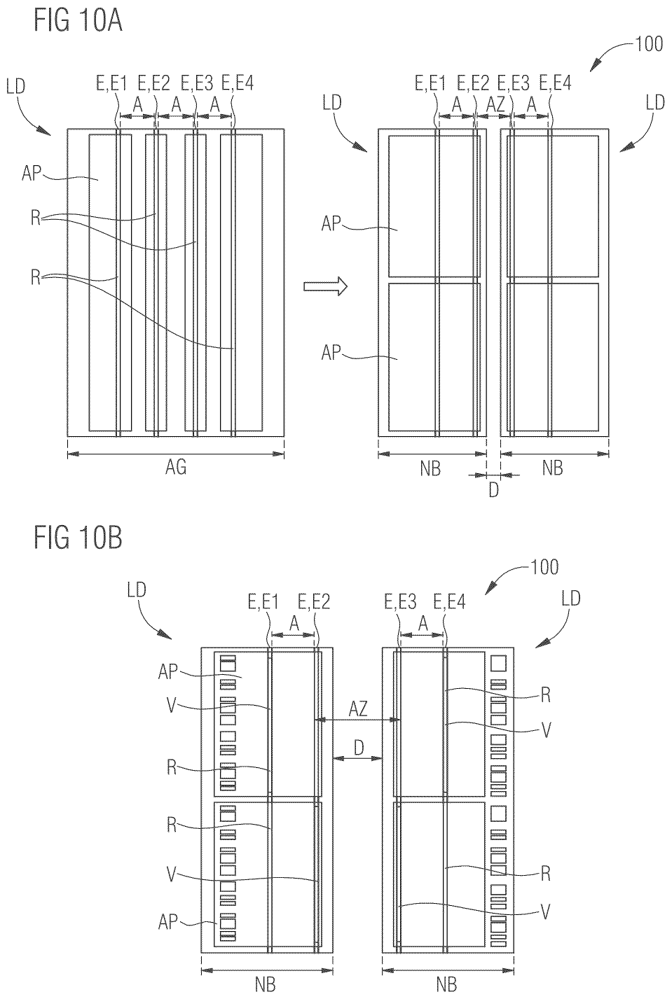

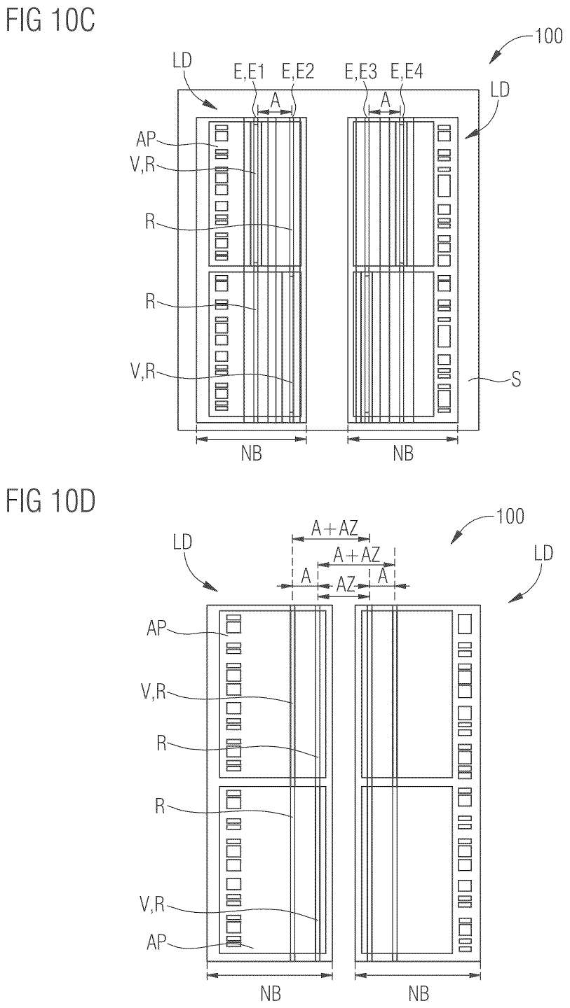

FIG. 10A shows that the semiconductor chip LD can have separate sub-regions, in particular separate emitter regions E1 to E4. On the left side, the semiconductor chip LD is formed to be contiguous. The semiconductor chip LD on the left side can have a single semiconductor body HL with the emitter regions E1 to E4. FIG. 10A shows on the right side two separate semiconductor bodies HL or two separate semiconductor chips LD each having two emitter regions E1 and E2 or E3 and E4.

On the left side in FIG. 10A, a semiconductor chip having four emitters or emitter regions E1-E4 is schematically shown. Such a semiconductor chip can have a high yield loss, since all four emitters or emitter regions E1-E4 are in spec and in sum should have for instance 10 nm wavelength broadening. High effort is needed to achieve the four different wavelengths on one chip.

The semiconductor chip LD can be divided into two chip regions, each with two emitters or emitter regions at half chip width (see right side in FIG. 10A). Only two emitters or two emitter regions should be in spec. This results in a significantly higher yield, since at most only one emitter or only one emitter region or one chip region is shifted in wavelength. Thus, it requires significantly less effort in the fabrication of the individual chip areas. It is also possible for the chip regions to each be formed as a single semiconductor chip.

In particular, FIG. 10A shows on the right side two separate semiconductor chips LD which may be arranged on a common carrier S. FIGS. 10B to 10D also show two separate semiconductor chips LD that can be arranged on a common carrier S. In FIGS. 10A to 10D, no carrier S is explicitly shown in some cases for reasons of clarity.

The two semiconductor chips 10C are spatially spaced apart from each other by a lateral intermediate region D or by a lateral distance D. The lateral intermediate region D can be from 5 μm to 50 μm wide.

A lateral distance A between two adjacent emitter regions E1-E4 can be from 20 μm to 60 μm, for instance 25 μm±5 μm, 30 μm±5 μm, 35 μm±5 μm, or 50 μm±5 μm. For example, the lateral distance A is 50 μm. For example, the lateral distance A is indicated by the distance between two emission points of the two adjacent emitter regions E on a lateral surface LS of the semiconductor chip LD or on a lateral surface of the component 100.

The lateral distance D between two adjacent semiconductor chips LD may be larger or smaller than the lateral distance A between two adjacent emitter regions E. In particular, the intermediate region D between two adjacent semiconductor chips LD is configured to set a lateral distance AZ between two outer adjacent emitter regions E of the adjacent semiconductor chips LD.

It is possible that the component 100 has an equidistant lateral separation distance for all emitter regions E1-E4. In this case, the lateral distance AZ between two outer adjacent emitter regions E of the adjacent semiconductor chips LD is identical to the lateral distance A between the adjacent emitter regions E of the same semiconductor chip LD. For example, the equidistant lateral pitch distance is about 50 μm. The equidistant pitch distance can also be 30 μm +5 μm, 35 μm±5 pm, 40 μm±5 μm, 45 μm±5 μm or 50 μm±5 μm.

Each of the semiconductor chips LD shown in FIGS. 10B to 10D can have a lateral width NB of for instance 150 μm. The semiconductor chip LD with four emitter regions E1-E4 shown on the left side of FIG. 10A can have a width AG of about 300 μm.

The lateral widths given in connection with FIGS. 10A to 10D are given by way of example only. The disclosure is not limited to these quantities.

The chip regions or semiconductor chips LD shown on the right side of FIG. 10A can be fixed, in particular soldered, to a carrier S such that a predetermined distance between the emitter regions or between the chip regions can be maintained up to manufacturing tolerances of, for example, +/−2 μm. The distance between the emitter regions E or between the chip areas can be 50 μm or smaller, for example 30 μm, or 20 μm, 10 μm or smaller, for example from 2 μm to 5 μm. With the combination of the chip regions or different semiconductor chips LD, a wavelength broadening of about 10 nm (FWHM) can be achieved. In particular, the semiconductor chip LD has more than one resonator. For example, the number of resonators of a semiconductor chip is two, three, four or six, for example from 2 to 6, from 2 to 4 or from 4 to 6.

Such semiconductor chips LD are particularly suitable in some applications where the coherence (narrow spectral width) of the laser emission normally causes problems. Such problems are for example optical artifacts in the image display, which are caused for example by the interaction of small spectral bandwidth of the emission and/or by periodic structures, for example by diffractive optical structures, in the beam path. To circumvent this problem, the semiconductor chips LD described here can be used. With such semiconductor chips LD the width of the spectral emission can be enlarged. One way to achieve the increase of the width of the spectral emission is to superimpose spectra of individual ridges with a small wavelength offset. Often a spectral width (wavelength broadening) of about 10 nm (FWHM) is desirable. To achieve this value, the wavelength offset between emitters or between emitter regions on a semiconductor chip LD can be about 2 μm-5 μm between individual resonators on a semiconductor chip LD.

The component 100 has a plurality of resonators, wherein the semiconductor chips LD and the emitter regions E, E1, E2, E3, and E4 are arranged adjacent to each other such that spectra of individual emitter regions E, E1, E2, E3, and E4 are superimposed with a wavelength offset during operation of the component 100. In particular, the wavelength offset is from 2 μm to 5 μm between individual resonators. As a result, a spectral width of 10 nm +/−5 nm can be achieved.

The embodiment shown in FIG. 10B essentially corresponds to the embodiment shown on the right side of FIG. 10A. In contrast, the through-contacts V are shown schematically. Due to the specific design of the through-contacts V, each of the connection pads AP or each of the contact pads KP is configured for the electrical contacting of one single emitter or one single emitter region E1-E4 (see also FIGS. 2A to 3D). In top view, each of the connection pads AP or each of the contact pads KP may cover a plurality of emitters or emitter regions E1-E4. In all figures, the through-contacts V are more like local through-contacts V. Along the lateral direction, the through-contact V in particular does not extend over the entire width or length of the emitter or emitter region E1-E4 associated with it.

According to FIG. 10B, the lateral distance A between the adjacent emitter regions E1 and E2 or E3 and E4 of the same semiconductor chip LD may be about 30 μm or 50 μm. The lateral distance AZ between two outer adjacent emitter regions E2 and E3 of the adjacent semiconductor chips LD may be larger or smaller than the lateral distance A. For example, the lateral distance AZ is for instance 70 μm or 30 μm.

The embodiment shown in FIG. 10C is substantially the same as the embodiment shown in FIG. 10B, especially after the semiconductor chip LD or the plurality of semiconductor chips LD have been mounted on the carrier S.

The exemplary embodiment shown in FIG. 10D is essentially the same as the exemplary embodiment shown in FIG. 10A or 10B with different distances between the emitters or emitter regions E1-E4 or between the emitter regions or between the semiconductor chips LD. In particular, the lateral distance A is for instance 30 μm. The lateral distance AZ can be about 70 μm.

Thus, in FIGS. 10B to 10D, a component 100 is shown with a plurality of emitter regions E, E1, E2, E3 and E4, a plurality of connection pads AP and a plurality of through-contacts V. The connection pads AP are each configured to make electrical contact with one single emitter region E1, E2, E3 or E4. In top view, the connection pads AP can each overlap with at least two or with exactly two emitter regions E1 and E2 or E3 and E4.

The component 100 has at least two semiconductor chips LD, which are arranged next to one another on the carrier S and are electrically conductively connected to the carrier S via the structured contact structure of the carrier S. In particular, the semiconductor chips LD are different from a single-emitter and each have at least two emitter regions E. For example, the semiconductor chips LD are each formed as double-emitters. The semiconductor chips LD can each have a chip bottom side RS with at least two connection pads AP, wherein in each case, the at least two connection pads AP are configured for making electrical contact with only one single emitter region E and, in top view, overlap with at least two emitter regions E.

The semiconductor chips LD and the emitter regions E can be arranged next to each other in such a way that a wavelength broadening of 10 nm +/−5 nm is achievable. A component 100 with such semiconductor chips LD can find application in AR glasses, VR glasses or in data glasses for increasing the image quality due to the wavelength expansion.

In FIGS. 10B to 10D, the semiconductor chips LD are each formed as double-emitters having exactly two emitter regions E. The component 100 may have exactly two semiconductor chips LD or more than two semiconductor chips LD, such as three or four semiconductor chips LD. Deviating from FIGS. 10B to 10D, it is possible that the semiconductor chips LD are each formed as triple-emitters having exactly three emitter regions E. In particular, the emitter regions E are each formed to generate coherent radiation. The semiconductor chips LD can be constructed in the same way.

The invention is not restricted to the exemplary embodiments by the description of the invention made with reference to exemplary embodiments. The invention rather comprises any novel feature and any combination of features, including in particular any combination of features in the claims, even if this feature or this combination is not itself explicitly indicated in the claims or exemplary embodiments.

1. A semiconductor chip having a structured chip bottom side, which is configured for electrical and thermal connection of the semiconductor chip, wherein
the semiconductor chip comprises emitter regions configured for generating electromagnetic radiation,
the structured chip bottom side comprises connection pads configured for the electrical connection of the emitter regions and
the connection pads are p-contacts or n-contacts and in top view, either all connection pads formed as p-contacts or all connection pads formed as n-contacts overlap in each case with at least two of the emitter regions and are each configured for the electrical connection of only one of the emitter regions

2. The semiconductor chip according to claim 1 comprising a chip top side and a lateral surface, wherein
the lateral surface connects the chip top side to the chip bottom side,
the semiconductor chip is formed as an edge-emitting semiconductor chip, and
during operation of the semiconductor chip, electromagnetic radiation is coupled out from the semiconductor chip at the lateral surface.

3. The semiconductor chip according to claim 1, wherein in top view, all connection pads, which are formed either as p-contacts or as n-contacts, overlap in each case with three, four or with all emitter regions of the semiconductor chip.

4. The semiconductor chip according to claim 1, wherein the connection pads are p-contacts, and in addition to the connection pads formed as p-contacts, the semiconductor chip has further connection pads, wherein the further connection pads form n-contacts of the semiconductor chip, and the p-contacts and n-contacts of the semiconductor chip are located on a common contacting plane.

5. The semiconductor chip according to claim 1, which comprises a semiconductor body with the emitter regions, an electrical distribution layer and an insulating layer, wherein
the insulating layer is arranged in vertical direction between the semiconductor body and the connection pads,
the insulating layer has at least one opening, in which an electrically conductive through-contact is formed, and
one of the connection pads is electrically conductively connected to the electrical distribution layer via the through-contact.

6. The semiconductor chip according to claim 5, wherein a plurality of through-contacts are arranged in the insulating layer, and wherein the electrical distribution layer is electrically conductively connected to a plurality of connection pads via the plurality of through-contacts.

7. The semiconductor chip according to claim 5, wherein the insulating layer forms a single insulating plane of the semiconductor chip between the electrical distribution layer and the chip bottom side.

8. The semiconductor chip according to 5 comprising a plurality of connection pads and through-contacts, wherein
the connection pads are each configured to make electrical contact with one single emitter region, and
in top view, the connection pads each overlap with at least two or with several emitter regions.

9. The semiconductor chip according to claim 1, which, in addition to the connection pads, comprises further connection pads, wherein the connection pads and the further connection pads form p-contacts and n-contacts of the semiconductor chip, and wherein the p-contacts and the n-contacts of the semiconductor chip are located on a common contacting plane.

10. The semiconductor chip according to claim 1, wherein the emitter regions of the semiconductor chip run parallel to one another and are each formed as a ridge region, the emitter regions being configured for generating coherent electromagnetic radiation.

11. The semiconductor chip according to claim 1, wherein the structured chip bottom side with the connection pads is formed in a honeycombed or matrix-like manner.

12. A component (100) having at least one semiconductor chip according to claim 1 and a carrier, wherein the at least one semiconductor chip is arranged on the carrier and is electrically conductively connected to the carrier via a structured contact structure of the carrier.

13. The component according to claim 12, wherein
the semiconductor chip has a semiconductor body, the semiconductor body being electrically conductively connected to contact pads on the carrier via an electrical distribution layer and via the connection pads on the chip bottom side,
the electrical distribution layer is arranged between the semiconductor body and the carrier, and
a single insulating layer is arranged between the electrical distribution layer and the carrier.

14. The component according to claim 12 comprising a plurality of emitter regions, a plurality of connection pads, and a plurality of through-contacts, wherein
the connection pads are each configured to make electrical contact with one single emitter region, and
in top view, the connection pads each overlap with at least two or with several emitter regions.

15. The component according to claims 12 comprising a plurality of emitter regions, a plurality of connection pads, and a plurality of through-contacts, wherein
the emitter regions are each electrically conductively connected to contact pads of the structured contact structure of the carrier via a plurality of connection pads and a plurality of through-contacts, and
the connection pads are each assigned to at most one single emitter region of the emitter regions.

16. The component according to claim 12, wherein the chip bottom side of the semiconductor chip and/or the structured contact structure of the carrier are/is formed in a honeycombed or matrix-like manner.

17. The component according to claim 12 comprising a further semiconductor chip which is arranged next to the semiconductor chip on the carrier and is electrically conductively connected to the carrier via the structured contact structure of the carrier, wherein
the semiconductor chips are different from a single-emitter and each have at least two emitter regions,
the semiconductor chips each have a chip bottom side with at least two connection pads, and
the at least two connection pads are configured for making electrical contact with one single emitter region and, in top view, each overlap with at least two emitter regions.

18. The component according to claim 17, comprising a plurality of resonators, wherein the semiconductor chips and the emitter regions are arranged next to each other that during operation of the component, spectra of individual emitter regions are superimposed with a wavelength offset which is from 2 μm to 5 μm between the individual resonators, thereby achieving a spectral width of 10 nm +/−5 nm.

19. A semiconductor chip having a structured chip bottom side which is configured for electrical and thermal connection of the semiconductor chip, wherein
the semiconductor chip comprises emitter regions configured for generating electromagnetic radiation,
the structured chip bottom side comprises connection pads configured for the electrical connection of the emitter regions, and
the connection pads are p-contacts or n-contacts and in top view, either all connection pads formed as p-contacts or all connection pads formed as n-contacts overlap in each case with all emitter regions of the semiconductor chip and are each configured for the electrical connection of only one of the emitter regions.

20. A semiconductor chip having a structured chip bottom side which is configured for electrical and thermal connection of the semiconductor chip, wherein
the semiconductor chip comprises emitter regions configured for generating electromagnetic radiation,
the structured chip bottom side comprises connection pads configured for the electrical connection of the emitter regions,
the connection pads are p-contacts and in top view, all connection pads formed as p-contacts overlap in each case with at least two of the emitter regions and are each configured for the electrical connection of only one of the emitter regions, and
in addition to the connection pads formed as p-contacts, the semiconductor chip has further connection pads, wherein the further connection pads form n-contacts of the semiconductor chip, and the p-contacts and n-contacts of the semiconductor chip are located on a common contacting plane.
